(19) United States
(12) Patent Application Publication
(10) Pub. No.: US 2025/0266391 A1
(43) Pub. Date: Aug. 21, 2025

(54) LASER ASSISTED BONDING METHOD

(71) Applicant: JCET STATS ChipPAC Korea Limited, Incheon (KR)

(72) Inventors: YeoJun YUN, Incheon (KR); SeungHyun LEE, Incheon (KR); HeeSoo LEE, Incheon (KR)

(21) Appl. No.: 19/055,528

(22) Filed: Feb. 18, 2025

(30) Foreign Application Priority Data
Feb. 20, 2024 (CN) 202410189497.X

(51) Int. Cl. H01L 23/00; H01L 21/48; H01L 21/60; H01L 23/31

(52) U.S. Cl. CPC H01L 24/81; H01L 21/4853; H01L 21/60; H01L 23/3121; H01L 24/13; H01L 2021/60112; H01L 2021/60202; H01L 2224/11552; H01L 2224/11849; H01L 2224/81203; H01L 2224/81224; H01L 2924/10253

(57) ABSTRACT

A laser assisted bonding method comprises placing a semiconductor die on a substrate, wherein the semiconductor die has on its back surface solder bumps and on its front surface an anti-reflection layer for infrared laser; and irradiating an infrared laser beam to the semiconductor die through the anti-reflection layer, to reflow the solder bumps between the semiconductor die and the substrate via heat generated due to energy of the infrared laser beam absorbed by the semiconductor die, wherein the anti-reflection layer is configured to reduce reflection of the infrared laser beam from the semiconductor die.

### TECHNICAL FIELD

The present application generally relates to semiconductor technology, and more particularly, to a laser assisted bonding method.

### BACKGROUND OF THE INVENTION

Semiconductor packaging is an important part of semiconductor manufacturing and design. The semiconductor packaging process may affect power, performance, cost and basic functionalities of all semiconductor chips. Typically, semiconductor dice are first fabricated at wafer level and then each semiconductor die may be attached onto a package substrate to form an integrated semiconductor package.

The attaching process of the semiconductor die on the package substrate can be conducted by a laser assisted bonding device, for example. During the bonding process, the bonding device picks up a semiconductor die using vacuum and then places the semiconductor die on a package substrate. A heating process may be conducted to heat solder bumps beneath the semiconductor die using infrared laser, which allows the solder bumps to form electrical connection between the semiconductor die and the package substrate. However, it is noted that some laser assisted bonding devices are low in efficiency.

Therefore, a need exists for further improvement of the laser assisted bonding method.

### SUMMARY OF THE INVENTION

An objective of the present application is to provide a laser assisted bonding method with improved efficiency.

According to an aspect of the present application, there is provided a laser assisted bonding method. The method comprises: placing a semiconductor die on a substrate, wherein the semiconductor die has on its front surface an anti-reflection layer for infrared laser, and solder bumps are formed between the substrate and the semiconductor die; and irradiating an infrared laser beam to the semiconductor die through the anti-reflection layer, to reflow the solder bumps between the semiconductor die and the substrate via heat generated due to energy of the infrared laser beam absorbed by the semiconductor die, wherein the anti-reflection layer is configured to reduce reflection of the infrared laser beam from the semiconductor die.

According to another aspect of the present application, a laser assisted bonding method is provided. The method comprises: placing a semiconductor die on a substrate, wherein the semiconductor die has on its front surface an anti-reflection layer for infrared laser, and solder bumps are formed between the substrate and the semiconductor die; compressing the semiconductor die against a substrate via an infrared-transparent chase; and irradiating from an infrared laser source an infrared laser beam to the semiconductor die through the infrared-transparent chase and the anti-reflection layer when the semiconductor die is pressed against the substrate, to reflow the solder bumps between the semiconductor die and the substrate via heat generated due to energy of the infrared laser beam absorbed in the semiconductor die, wherein the anti-reflection layer is configured to reduce reflection of the infrared laser beam from the semiconductor die.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1C illustrate a laser assisted bonding method according to an embodiment of the present application.

FIGS. 2A to 2C illustrate a laser assisted bonding method according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As mentioned above, typically, semiconductor dice are first fabricated at wafer level and then each semiconductor die may be attached onto a package substrate after the semiconductor wafer is singulated into pieces or units, to form an integrated semiconductor package. The attaching process of the semiconductor die to the package substrate can be conducted by a laser assisted bonding device, which can utilize vacuum to pick up and move the semiconductor die onto a substrate, and heat solder bumps underneath the semiconductor die using an infrared laser beam to bond the semiconductor die onto the substrate.

However, the inventors of the present application found that when the solder bumps are heated by the laser assisted bonding device, the efficiency of the laser heating is relatively low, and thus it is required to increase laser power or duration of the laser heating to have the solder bumps reach a satisfactory temperature that is sufficient to reflow. The inventors further found that during the laser heating too much infrared laser energy was wasted due to a significant difference in refractive index between the semiconductor die and the environment. In other words, a significant portion of the infrared laser emitted towards the semiconductor die may be reflected at a top surface of the semiconductor die and may not be absorbed by the semiconductor die. Thus, less laser energy can be converted into heat to reflow the solder bumps. For example, it is found that only about 30% of the infrared laser energy may be absorbed by a silicon die during the laser assisted bonding process, which means that 70% of the infrared laser energy may be reflected by the semiconductor die and cannot be utilized for heating.

To address the above issue, a new laser assisted bonding method is provided. An anti-reflection layer is formed on a front surface of a semiconductor die to be bonded. The anti-reflection layer can reduce reflection loss during the laser assisted bonding process to improve the efficiency of the laser assisted bonding. For example, the anti-reflection layer can have a refractive index between air and a material of the semiconductor die for infrared light.

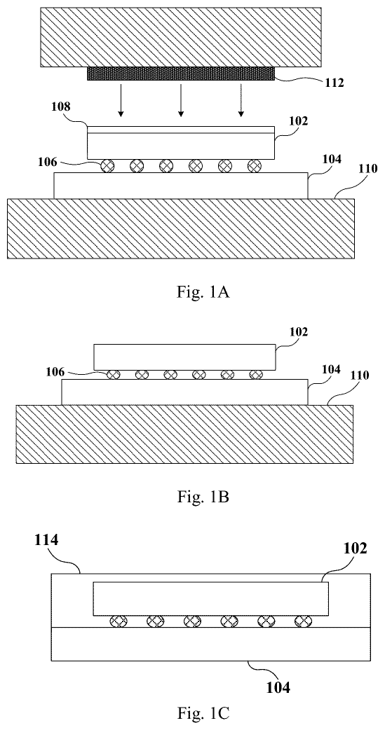

FIGS. 1A to 1C illustrate a laser assisted bonding method according to an embodiment of the present application. In some embodiments, the laser assisted bonding method can be used to bond a semiconductor die such as a silicon die onto a substrate through solder bumps.

As shown in FIG. 1A, a semiconductor die 102 may be provided, which has a front surface and a back surface. The semiconductor die 102 is to be attached onto a substrate 104 through bonding. Underneath the back surface of the semiconductor die 102 solder bumps 106 are formed, which can be made of tin or other suitable materials. In some embodiments, multiple conductive pads can be formed on a front surface of the substrate 104 for the attachment of the semiconductor die 102 thereon. It can be appreciated that the multiple conductive pads may be exposed portions of interconnect wires formed within the substrate 104. Similarly, conductive pads may be formed on the back surface of the semiconductor die 102 where the solder bumps 106 are formed. In some embodiments, the solder bumps 106 may be formed on the substrate 104 instead of the on the back surface of the semiconductor die 102, before the substrate 104 and the semiconductor die 102 are placed together.

An anti-reflection layer 108 may be formed on the front surface of the semiconductor die 102, which can be used to reduce mismatch in refractive index for infrared light between the material of the semiconductor die 102 and the environment which is generally air. Infrared light generally has a wavelength ranging from 0.75 micrometer to 1000 micrometers, but short infrared light which ranges from 0.75 micrometer to 3 micrometers is more suitable for heating because it has higher energy compared to middle infrared light and far infrared light. In the embodiment, infrared light with a wavelength of 900 nm to 1100 nm is used for the laser assisted bonding process. Accordingly, the anti-reflection layer 108 may have a refractive index between the semiconductor material and air for infrared laser with the wavelength of 900 nm to 1100 nm. In particular, silicon has a refractive index of 3.5 for infrared laser with the wavelength of 900 nm to 1100 nm and air has a refractive index of 1 for infrared laser with the wavelength of 900 nm to 1100 nm, and therefore the anti-reflection layer 108 may have a refractive index ranging from 1 to 3.5 for such infrared laser, preferably ranging from 1.2 to 3.3 or more preferably ranging from 1.5 to 3.0. For example, the anti-reflection layer 108 may be formed of one or more of the following materials: ZnS, TiO₂, SiO₂, CeF₃, MgF₂, or any other suitable materials. In particular, the anti-reflection layer 108 is generally formed with a better uniformity and quality which can be, for example, formed using e-beam evaporation, sputtering, or spin coating. Furthermore, depending on the thickness of the anti-reflection layer 108, different processes may be selected for forming the anti-reflection layer 108. For example, the spin coating method can be used to deposit and form an anti-reflection layer with a thickness from 1 micrometer to 10 micrometers, while the e-beam evaporation and sputtering processes can be used to form thinner anti-reflection layers which may be below 1 micrometer, for example.

In some embodiments, the anti-reflection layer 108 may be formed on the semiconductor die 102 by e-beam evaporation, sputtering, dispensing, spin-coating or film-type attaching. For example, a liquid or an emulsion or suspension mixture may be dispensed on a semiconductor wafer such as a silicon wafer to form the anti-reflection layer 108. After the active material(s) solidify and form the anti-reflection layer 108, the semiconductor wafer can be singulated into individual units, i.e., the semiconductor dices. In some embodiments, the anti-reflection layer 108 formed on the semiconductor die 102 may have a thickness ranging from 500 nm to 20 micrometers, or preferably ranging from 1 micrometer to 10 micrometers. In some preferred embodiments, the anti-reflection layer 108 may have a thickness which is N times a quarter of the wavelength of the infrared light, wherein N is an odder integer.

In some embodiments, the anti-reflection layer 108 may be maintained with the semiconductor die 102 after the bonding process. However, in some other embodiments, the anti-reflection layer 108 may be removed from the semiconductor die 102 after the bonding process. Thus, it is preferred in some embodiments that the anti-reflection layer 108 can be easily removed from the semiconductor die 102 later without causing any substantial damages to the semiconductor die 102 and the substrate 104. For example, anti-reflection layers with a thickness of 10 micrometers or less can be removed using proper chemical etchant(s), or using a mechanical method such as polishing.

In some embodiments, the anti-reflection layer 108 may be a single layer, while in some alternative embodiments, the anti-reflection layer 108 may be consisted of multiple sublayers, each of which may have a different refractive index for infrared light. For example, the anti-reflection layer 108 may include at least a first sublayer and a second sublayer. The second sublayer is closer to the semiconductor die 102 than the first sublayer, and the second sublayer has a refractive index greater than that of the first sublayer. In this way, the anti-reflection layer 108 may have a gradually increasing refractive index when it gets closer to the semiconductor die 102, to mitigate the mismatch in refractive index between air and the base material of the semiconductor die 102.

Referring back to FIG. 1A, the substrate 104 may be placed on a carrier 110 such as a platform or a mechanical support. Furthermore, the semiconductor die 102 may be placed on the substrate 104, with the solder bumps 106 in direct contact with the substrate 104. The anti-reflection layer 108 topmost of the semiconductor die 102 may be exposed to a laser source 112 positioned above the semiconductor die 102. During the bonding process, the laser source 112 may be activated to irradiate an infrared laser beam to the semiconductor die 102. The infrared laser beam may transmit through the anti-reflection layer 108 till the semiconductor die 102. In this way, the semiconductor die 102 may receive the laser energy and convert it into heat due to indirect band gap characteristic of the base material of the semiconductor die 102. As more heat is accumulated within the semiconductor die 102, the heat may transfer to the solder bumps 106 underneath the semiconductor die 102 so that the solder bumps 106 can be reflowed. In particular, when the temperature of the semiconductor die 102 and the solder bumps 106 increases, the solder bumps 106 may start to melt and infiltrate on the conductive pads on the substrate 104. Due to the existence of the anti-reflection layer 108 on the front surface of the semiconductor die 102, less laser light may be reflected at the interface between air and the semiconductor die 102, and thus the efficiency of the laser energy can be improved compared with conventional laser assisted bonding methods without forming the anti-reflection layer on the semiconductor die.

Referring to FIG. 1B, after the laser irradiation is applied to the semiconductor die 102, the laser source may be removed, leaving the semiconductor die 102 bonded with the substrate 104 through the reflowed solder bumps 106 on the carrier 110. Afterwards, the anti-reflection layer may be removed from the semiconductor die 102. For example, the anti-reflection layer consisting of SiO₂ may be removed using a proper chemical etchant such as hydrofluoric acid (HF). However, it can be appreciated that in some embodiments, the anti-reflection layer may be maintained with the semiconductor die 102.

Referring to FIG. 1C, one or more additional processes may be performed on the semiconductor die 102 and the substrate 104. For example, an encapsulant layer 114 may be formed on the substrate 104 to encapsulate the semiconductor die 102 and protect it from the environment and damages. In some embodiments, a metal layer (not shown) such as a copper layer may be formed over the encapsulant layer 114, which serves as an electromagnetic interference shielding layer for the semiconductor package so formed.

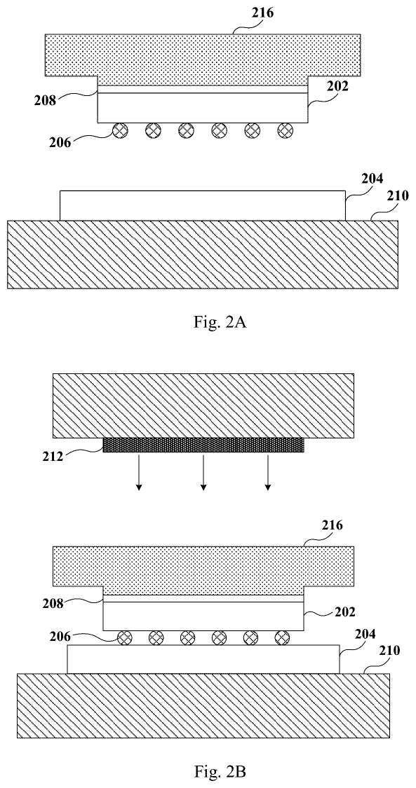

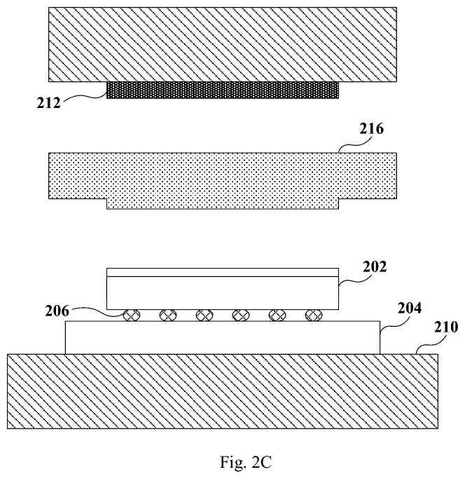

FIGS. 2A to 2C illustrate a laser assisted bonding method according to another embodiment of the present application. In the embodiment, the laser assisted bonding method is a compression bonding method, i.e., a compression force may be applied to a semiconductor die to help the bonding process.

As shown in FIG. 2A, a semiconductor die 202 is provided, with an anti-reflection layer 208 formed on its front surface and solder bumps 206 formed on its back surface. A chase 216 is used to pick up the semiconductor die 202 and move the semiconductor die 202 to a bonding position on a substrate 204 which is placed on a carrier 210. In some embodiments, the chase 216 may use vacuum to pick up the semiconductor die 202. The chase 216 is transparent to infrared light so that infrared light can transmit through the chase 216.

Next, as shown in FIG. 2B, the semiconductor die 202 may be pressed against the substrate 204 by the chase 216. At the same time, a laser source 212 which is placed above the chase 216 may irradiate an infrared laser beam to the semiconductor die 202 through the infrared-transparent chase 216. Since the infrared-transparent chase 216 is in direct contact with the anti-reflection layer 208 on the semiconductor die 202, the anti-reflection layer 208 may reduce reflection of the infrared light from the semiconductor die 202 back towards to the chase 216, thereby improving light transmission into the semiconductor die 202 where the laser energy can be converted into heat. In this way, the solder bumps 206 can be reflowed in a more efficient way compared with conventional bonding processes, to form sufficient bonding between the semiconductor die 202 and the substrate 204 through the solder bumps 206. In some embodiments, a flux material may be disposed on surfaces of the solder bumps 206.

As mentioned above, since the infrared-transparent chase 216 is in direct contact with the anti-reflection layer 208 on the semiconductor die 202, the anti-reflection layer 208 may have a refractive index for infrared laser between that of a material of the chase 216 and that of a base material of the semiconductor die 202. It can be appreciated that a proper material may be selected for the anti-reflection layer 208 depending on the materials of the chase 216 and the semiconductor die 202. In some embodiments, the anti-reflection layer 208 may include at least a first sublayer and a second sublayer which is closer to the semiconductor die 202, and the second sublayer may have a refractive index greater than that of the first sublayer.

Next, as shown in FIG. 2C, after the solder bumps 206 are reflowed and infiltrate on the conductive pads on the substrate 204, the laser source 212 may be deactivated and the infrared-transparent chase 216 may be lifted up and away from the semiconductor die 202 and the substate 204 on the carrier 210. The bonding process is thus completed. In some embodiments, subsequent packaging processes such as encapsulation and electromagnetic interference shielding may be performed on the bonded semiconductor die 202 and substate 204 to form a semiconductor package. Optionally, the anti-reflection layer may be removed from the semiconductor die 202 before these subsequent packaging processes.

The discussion herein includes numerous illustrative figures that show various portions of a laser assisted bonding method. For illustrative clarity, such figures do not show all aspects of each example method. Any of the example methods provided herein may share any or all characteristics with any or all other methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A laser assisted bonding method, comprising:
placing a semiconductor die on a substrate, wherein the semiconductor die has on its front surface an anti-reflection layer for infrared laser, and solder bumps are formed between the substrate and the semiconductor die; and
irradiating an infrared laser beam to the semiconductor die through the anti-reflection layer, to reflow the solder bumps between the semiconductor die and the substrate via heat generated due to energy of the infrared laser beam absorbed by the semiconductor die, wherein the anti-reflection layer is configured to reduce reflection of the infrared laser beam from the semiconductor die.

2. The method of claim 1, the method further comprising:
removing the anti-reflection layer from the semiconductor die after the solder bumps are reflowed.

3. The method of claim 1, wherein the anti-reflection layer has a refractive index for infrared laser between that of air and that of a base material of the semiconductor die.

4. The method of claim 3, wherein the semiconductor die comprises a base material of silicon, and the anti-reflection layer has a refractive index ranging from 1 to 3.5 for infrared laser.

5. The method of claim 1, wherein the anti-reflection layer comprises at least a first sublayer and a second sublayer which is closer to the semiconductor die, and wherein the second sublayer has a refractive index greater than that of the first sublayer.

6. The method of claim 1, wherein the method further comprises:
pressing the semiconductor die against the substrate via an infrared-transparent chase when irradiating the semiconductor die with the infrared laser beam, wherein the infrared laser beam is emitted from a laser source above the infrared-transparent chase.

7. The method of claim 1, wherein the infrared laser beam has a wavelength ranging from 900 nm to 1100 nm.

8. The method of claim 1, wherein the anti-reflection layer is formed by e-beam evaporation, sputtering, dispensing, spin-coating or film-type attaching.

9. A laser assisted bonding method, comprising:
placing a semiconductor die on a substrate, wherein the semiconductor die has on its front surface an anti-reflection layer for infrared laser, and solder bumps are formed between the substrate and the semiconductor die;
compressing the semiconductor die against the substrate via an infrared-transparent chase; and
irradiating from an infrared laser source an infrared laser beam to the semiconductor die through the infrared-transparent chase and the anti-reflection layer when the semiconductor die is pressed against the substrate, to reflow the solder bumps between the semiconductor die and the substrate via heat generated due to energy of the infrared laser beam absorbed in the semiconductor die, wherein the anti-reflection layer is configured to reduce reflection of the infrared laser beam from the semiconductor die.

10. The method of claim 9, the method further comprising:
removing the anti-reflection layer from the semiconductor die after the solder bumps are reflowed.

11. The method of claim 9, wherein the anti-reflection layer has a refractive index for infrared laser between that of the infrared-transparent chase and that of a base material of the semiconductor die.

12. The method of claim 9, wherein the anti-reflection layer comprises at least a first sublayer and a second sublayer which is closer to the semiconductor die, and wherein the second sublayer has a refractive index greater than that of the first sublayer.

13. The method of claim 9, wherein the infrared laser beam has a wavelength ranging from 900 nm to 1100 nm.

14. The method of claim 9, wherein the anti-reflection layer is formed by e-beam evaporation, sputtering, dispensing, spin-coating or film-type attaching.

15. A semiconductor package formed using the method of claim 1.

16. A semiconductor package formed using the method of claim 9.
